(19) United States
(12) Patent Application Publication
(10) Pub. No.: US 2025/0323170 A1
(43) Pub. Date: Oct. 16, 2025

(54) GLASS SUBSTRATE STACKING STRUCTURE AND METHOD OF MANUFACTURING THE SAME

(71) Applicant: ASTI GLOBAL INC., TAIWAN, Taichung City (TW)

(72) Inventor: CHIEN-SHOU LIAO, Taichung City (TW)

(21) Appl. No.: 19/176,312

(22) Filed: Apr. 11, 2025

Related U.S. Application Data
(60) Provisional application No. 63/632,917, filed on Apr. 11, 2024.

(51) Int. Cl. H01L 23/538; H01L 21/48; H01L 23/13; H01L 23/15; H01L 25/03; H01L 25/065

(52) U.S. Cl. CPC H01L 23/5385; H01L 21/4803; H01L 23/13; H01L 23/15; H01L 23/5386; H01L 23/5389; H01L 25/03; H01L 25/0655

(57) ABSTRACT

A glass substrate stacking structure and a method of manufacturing the same. The glass substrate stacking structure includes a basic glass substrate, a plurality of stacked glass substrates and a top glass substrate. The basic glass substrate has a basic glass adhesive portion therearound. Each stacked glass substrate has a first and a second stacked glass adhesive portion therearound. The top glass substrate has a top glass adhesive portion therearound. The basic glass substrate and the bottommost stacked glass substrate are connected to each other through the basic glass adhesive portion and the first stacked glass adhesive portion. The two adjacent stacked glass substrates are connected to each other through the first and the second stacked glass adhesive portion. The top glass substrate and the topmost stacked glass substrate are connected to each other through the top glass adhesive portion and the second stacked glass adhesive portion.

### CROSS-REFERENCE TO RELATED PATENT APPLICATION

This application claims the benefit of priority to the U.S. Provisional Patent Application Ser. No. 63/632,917, filed on Apr. 11, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a glass substrate stacking structure and a method of manufacturing the same, and more particularly to a thin glass substrate stacking structure and a method of manufacturing the same.

### BACKGROUND OF THE DISCLOSURE

In the related art, a glass substrate can be configured to be used as a circuit substrate. However, there is still room for improvement in the bonding method of multiple glass substrates.

### SUMMARY OF THE DISCLOSURE

In response to the above-referenced technical inadequacy, the present disclosure provides a glass substrate stacking structure and a method of manufacturing the same.

In order to solve the above-mentioned problems, one of the technical aspects adopted by the present disclosure is to provide a glass substrate stacking structure, which includes a basic glass substrate, a plurality of stacked glass substrates, a top glass substrate, a plurality of first conductive penetration bodies and a second conductive penetration body. The plurality of stacked glass substrates are sequentially stacked on the basic glass substrate. The top glass substrate is stacked on a topmost one of the plurality of stacked glass substrates. The plurality of first conductive penetration bodies are configured to respectively pass through the plurality of stacked glass substrates. The second conductive penetration body is configured to pass through the top glass substrate. The basic glass substrate has a basic glass adhesive portion therearound, each of the plurality of stacked glass substrates has a first stacked glass adhesive portion and a second stacked glass adhesive portion therearound, and the top glass substrate has a top glass adhesive portion therearound. The basic glass substrate and a bottommost one of the plurality of stacked glass substrates are configured to be connected to each other through the basic glass adhesive portion of the basic glass substrate and the first stacked glass adhesive portion of the bottommost stacked glass substrate. Two adjacent ones of the plurality of stacked glass substrates are configured to be connected to each other through the first stacked glass adhesive portion and the second stacked glass adhesive portion that are adjacent to each other. The top glass substrate and the topmost stacked glass substrate are configured to be connected to each other through the top glass adhesive portion of the top glass substrate and the second stacked glass adhesive portion of the topmost stacked glass substrate.

In order to solve the above-mentioned problems, another one of the technical aspects adopted by the present disclosure is to provide a glass substrate stacking structure, which includes a plurality of glass substrates stacked in sequence, at least one of the plurality of glass substrates being penetrated by a conductive penetration body, each of the plurality of glass substrates having at least one glass adhesive portion provided by the glass substrate itself and disposed therearound, two adjacent ones of the plurality of glass substrates being connected to each other through two adjacent ones of the plurality of glass adhesive portions, and each of the plurality of glass substrates having a thickness less than or equal to 100 μm.

In order to solve the above-mentioned problems, yet another one of the technical aspects adopted by the present disclosure is to provide a method of manufacturing a glass substrate stacking structure, which includes: providing a basic glass substrate, a plurality of stacked glass substrates and a top glass substrate; stacking the basic glass substrate, the plurality of stacked glass substrates and the top glass substrate in sequence; and then bonding the basic glass substrate, the plurality of stacked glass substrates and the top glass substrate together by laser processing. A plurality of first conductive penetration bodies are configured to respectively pass through the plurality of stacked glass substrates, and a second conductive penetration body is configured to pass through the top glass substrate. The basic glass substrate has a basic glass adhesive portion therearound, each of the plurality of stacked glass substrates has a first stacked glass adhesive portion and a second stacked glass adhesive portion therearound, and the top glass substrate has a top glass adhesive portion therearound. The basic glass substrate and a bottommost one of the plurality of stacked glass substrates are configured to be connected to each other through the basic glass adhesive portion of the basic glass substrate and the first stacked glass adhesive portion of the bottommost stacked glass substrate. Two adjacent ones of the plurality of stacked glass substrates are configured to be connected to each other through the first stacked glass adhesive portion and the second stacked glass adhesive portion that are adjacent to each other. The top glass substrate and the topmost stacked glass substrate are configured to be connected to each other through the top glass adhesive portion of the top glass substrate and the second stacked glass adhesive portion of the topmost stacked glass substrate.

Therefore, in the glass substrate stacking structure provided by the present disclosure, by virtue of “the basic glass substrate having a basic glass adhesive portion therearound,” “each of the plurality of stacked glass substrates having a first stacked glass adhesive portion and a second stacked glass adhesive portion therearound” and “the top glass substrate having a top glass adhesive portion therearound,” when the basic glass substrate, the plurality of stacked glass substrates and the top glass substrate are stacked in sequence, the basic glass substrate and a bottommost one of the plurality of stacked glass substrates are configured to be connected to each other through the basic glass adhesive portion of the basic glass substrate and the first stacked glass adhesive portion of the bottommost stacked glass substrate, two adjacent ones of the plurality of stacked glass substrates are configured to be connected to each other through the first stacked glass adhesive portion and the second stacked glass adhesive portion that are adjacent to each other, and the top glass substrate and the topmost stacked glass substrate are configured to be connected to each other through the top glass adhesive portion of the top glass substrate and the second stacked glass adhesive portion of the topmost stacked glass substrate.

Moreover, in the method of manufacturing the glass substrate stacking structure provided by the present disclosure, by virtue of “each of the plurality of glass substrates having at least one glass adhesive portion provided by the glass substrate itself and disposed therearound,” when the plurality of glass substrates stacked in sequence, two adjacent ones of the plurality of glass substrates can be connected to each other through two adjacent ones of the plurality of glass adhesive portions.

Furthermore, in the method of manufacturing the glass substrate stacking structure provided by the present disclosure, by virtue of “the basic glass substrate having a basic glass adhesive portion therearound,” “each of the plurality of stacked glass substrates having a first stacked glass adhesive portion and a second stacked glass adhesive portion therearound” and “the top glass substrate having a top glass adhesive portion therearound,” when the basic glass substrate, the plurality of stacked glass substrates and the top glass substrate are stacked in sequence, the basic glass substrate and a bottommost one of the plurality of stacked glass substrates are configured to be connected to each other through the basic glass adhesive portion of the basic glass substrate and the first stacked glass adhesive portion of the bottommost stacked glass substrate, two adjacent ones of the plurality of stacked glass substrates are configured to be connected to each other through the first stacked glass adhesive portion and the second stacked glass adhesive portion that are adjacent to each other, and the top glass substrate and the topmost stacked glass substrate are configured to be connected to each other through the top glass adhesive portion of the top glass substrate and the second stacked glass adhesive portion of the topmost stacked glass substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for manufacturing a glass substrate stacking structure according to a first embodiment of the present disclosure;

FIG. 2 is a schematic cross-sectional view of step S100 of the method for manufacturing the glass substrate stacking structure according to the first embodiment of the present disclosure;

FIG. 3 is a schematic cross-sectional view of step S102 of the method for manufacturing the glass substrate stacking structure according to the first embodiment of the present disclosure;

FIG. 4 is a schematic cross-sectional view of step S104 of the method for manufacturing the glass substrate stacking structure according to the first embodiment of the present disclosure (or a schematic cross-sectional view of the glass substrate stacking structure according to the first embodiment of the present disclosure);

FIG. 5 is a schematic cross-sectional view of the glass substrate stacking structure according to a second embodiment of the present disclosure;

FIG. 6 is a schematic cross-sectional view of the glass substrate stacking structure according to a third embodiment of the present disclosure (before laser welding);

FIG. 7 is a schematic cross-sectional view of the glass substrate stacking structure according to the third embodiment of the present disclosure (after laser welding);

FIG. 8 is a schematic cross-sectional view of the glass substrate stacking structure according to a fourth embodiment of the present disclosure;

FIG. 9 is a schematic cross-sectional view of the glass substrate stacking structure according to a fifth embodiment of the present disclosure (before laser welding); and

FIG. 10 is a schematic cross-sectional view of the glass substrate stacking structure according to the fifth embodiment of the present disclosure (after laser welding).

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

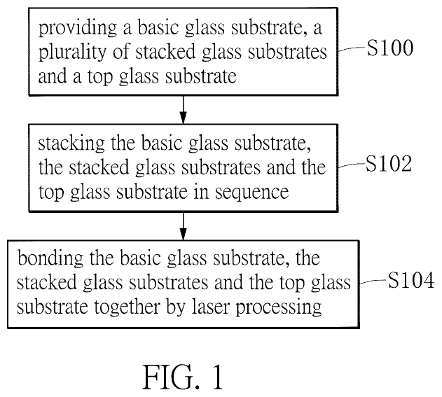

Referring to FIG. 1 to FIG. 10, the present disclosure provides a glass substrate stacking structure S and a method of manufacturing the glass substrate stacking structure S, in which the glass substrate stacking structure S includes a plurality of glass substrates (such as more than two glass substrates selected from a basic glass substrate 1, a plurality of stacked glass substrates 2 and a top glass substrate 3) stacked in sequence, and at least one of the glass substrates can be penetrated by a conductive penetration body (such as any one of a plurality of first conductive penetration bodies 4 and a second conductive penetration body 5). In addition, each of the glass substrates has at least one glass adhesive portion (such as at least one of a basic glass adhesive portion 100, a first stacked glass adhesive portion 201, a second stacked glass adhesive portion 202 and a top glass adhesive portion 300) provided by the glass substrate itself (that is to say, the at least one glass adhesive portion is provided by the glass substrate or belongs to the glass substrate itself) and disposed therearound, or a glass bonding material H may be provided around each glass substrate, and any two adjacent glass substrates can be connected to each other through two adjacent glass adhesive portions or the corresponding glass bonding material H. It should be noted that each of the glass substrates has a thickness less than or equal to 100 μm (such as any positive integer between 1 μm and 100 μm). However, the aforementioned details are disclosed for exemplary purposes only, and are not meant to limit the scope of the present disclosure.

### First Embodiment

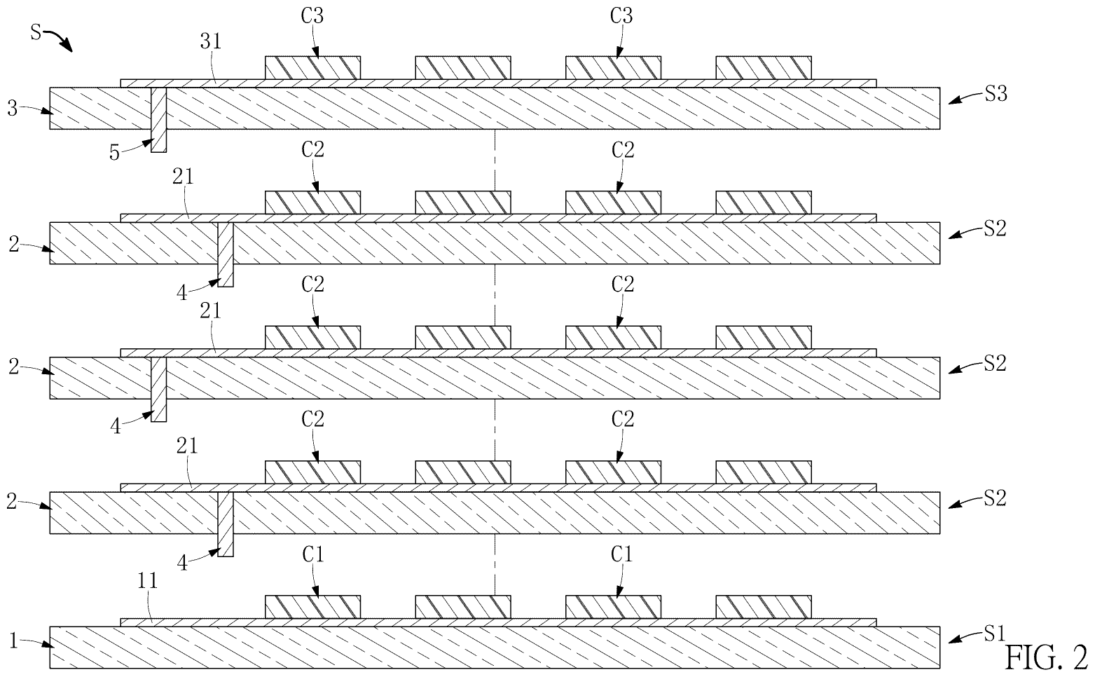

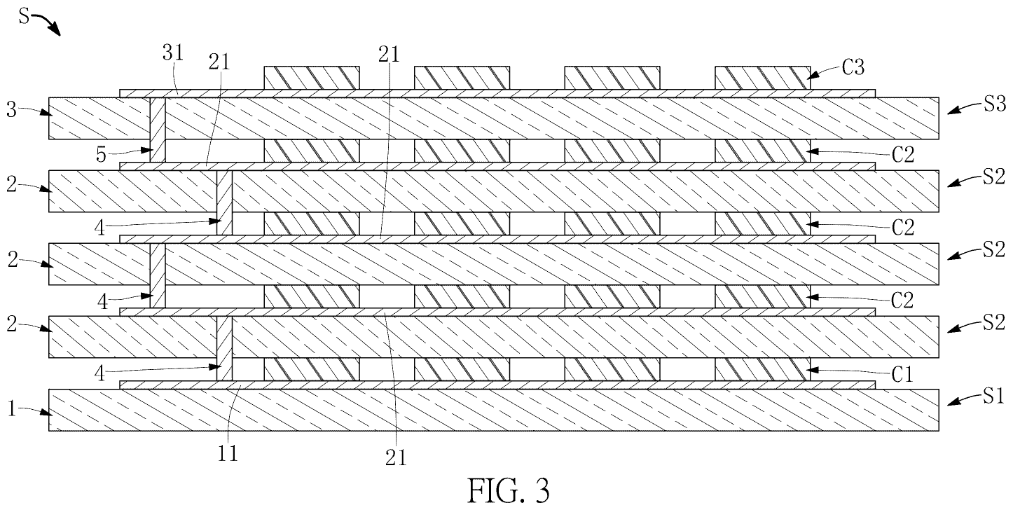

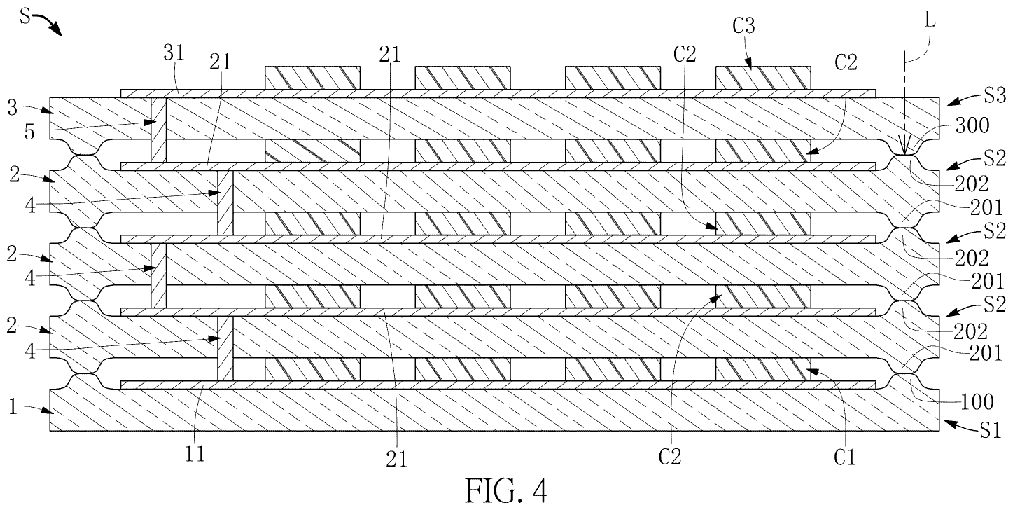

Referring to FIG. 1 to FIG. 4, a first embodiment of the present disclosure provides a method of manufacturing a glass substrate stacking structure S, which may at least include the following steps: firstly, referring to FIG. 1 and FIG. 2, providing a basic glass substrate 1, a plurality of stacked glass substrates 2 and a top glass substrate 3 (step S100); then, referring to FIG. 1, FIG. 2 and FIG. 3, stacking the basic glass substrate 1, the stacked glass substrates 2 and the top glass substrate 3 in sequence (step S102); next, referring to FIG. 1, FIG. 3 and FIG. 4, bonding the basic glass substrate 1, the stacked glass substrates 2 and the top glass substrate 3 together by laser processing (such as by a laser generating module or a laser generator that can provide at least one laser beam L) (step S104). It should be noted that as shown in FIG. 2 or FIG. 3, a plurality of first conductive penetration bodies 4 (such as a plurality of conductive vias, a plurality of conductive pillars, or any kind of conductive structures) can be configured to respectively pass through (penetrate) the stacked glass substrates 2, and a second conductive penetration body 5 (such as a plurality of conductive vias, a plurality of conductive pillars, or any kind of conductive structures) can be configured to pass through (penetrate) the top glass substrate 3. In one of the feasible embodiment, the multiple stacked glass substrates 2 can be pre-welded on the basic glass substrate 1 in sequence through laser processing (or laser welding) (that is to say, the basic glass substrate 1 can be configured as the base substrate, and the multiple stacked glass substrates 2 can be stacked on the basic glass substrate 1 in sequence through laser welding), and then the top glass substrate 3 is welded on the topmost stacked glass substrate 2 by laser processing (or laser welding). Therefore, the basic glass substrate 1, the multiple stacked glass substrates 2 and the top glass substrate 3 provided by the present disclosure can be sequentially stacked and then bonded in sequence by laser welding, or the basic glass substrate 1, the multiple stacked glass substrates 2 and the top glass substrate 3 can also be bonded in sequence by laser welding while being stacked. However, the aforementioned details are disclosed for exemplary purposes only, and are not meant to limit the scope of the present disclosure.

It should be noted that, for example, as shown in FIG. 4, in the step S104 of bonding (or welding) the basic glass substrate 1, the stacked glass substrates 2 and the top glass substrate 3 together by laser processing, the periphery of the basic glass substrate 1 can be cured or heated by the laser beam L to form a basic glass adhesive portion 100 (such as a surrounding basic glass adhesive layer that is continuous or discontinuous), the periphery of each stacked glass substrate 2 can be cured or heated by the laser beam L to form a first stacked glass adhesive portion 201 (such as a first surrounding stacked glass adhesive layer that is continuous or discontinuous) and a second stacked glass adhesive portion 202 (such as a second surrounding stacked glass adhesive layer that is continuous or discontinuous), and the periphery of the top glass substrate 3 can be cured or heated by the laser beam L to form a top glass adhesive portion 300 (such as a top surrounding glass adhesive layer that is continuous or discontinuous). Therefore, the basic glass substrate 1 and a bottommost one of the stacked glass substrates 2 can be configured to be connected (or bonded or welded) to each other through the basic glass adhesive portion 100 of the basic glass substrate 1 and the first stacked glass adhesive portion 201 of the bottommost stacked glass substrate 2, two adjacent ones of the stacked glass substrates 2 can be configured to be connected (or bonded or welded) to each other through the first stacked glass adhesive portion 201 and the second stacked glass adhesive portion 202 that are adjacent to each other, and the top glass substrate 3 and the topmost stacked glass substrate 2 can be configured to be connected (or bonded or welded) to each other through the top glass adhesive portion 300 of the top glass substrate 3 and the second stacked glass adhesive portion 202 of the topmost stacked glass substrate 2. However, the aforementioned details are disclosed for exemplary purposes only, and are not meant to limit the scope of the present disclosure.

Moreover, referring to FIG. 3 and FIG. 4, the first embodiment of the present disclosure further provides a glass substrate stacking structure S, which may at least include a basic glass substrate 1, a plurality of stacked glass substrates 2, a top glass substrate 3, a plurality of first conductive penetration bodies 4 and a second conductive penetration body 5. More particularly, the stacked glass substrates 2 can be sequentially stacked on the basic glass substrate 1, and the top glass substrate 3 can be stacked on a topmost one of the stacked glass substrates 2. In addition, the first conductive penetration bodies 4 can be configured to respectively pass through the stacked glass substrates 2, and the second conductive penetration body 5 can be configured to pass through the top glass substrate 3. It should be noted that, for example, the basic glass substrate 1 may have a thickness less than or equal to 100 μm (such as any positive integer between 1 μm and 100 μm), each of the stacked glass substrates 2 may have a thickness less than or equal to 100 μm (such as any positive integer between 1 μm and 100 μm), and the top glass substrate 3 may have a thickness less than or equal to 100 μm (such as any positive integer between 1 μm and 100 μm). However, the aforementioned details are disclosed for exemplary purposes only, and are not meant to limit the scope of the present disclosure.

For example, referring to FIG. 2 and FIG. 3, the basic glass substrate 1 can be configured to provide a basic conductive circuit layer 11 (or a basic circuit layout layer) and to carry a plurality of basic semiconductor chips C1 (such as a memory IC chip, a micro component IC chip, a logic IC chip, or an analog IC chip), and the basic semiconductor chips C1 can be electrically connected to the basic conductive circuit layer 11. Moreover, each of the stacked glass substrates 2 can be configured to provide a middle conductive circuit layer 21 (or a middle circuit layout layer) and to carry a plurality of middle semiconductor chips C2 (such as a memory IC chip, a micro component IC chip, a logic IC chip, or an analog IC chip), the middle semiconductor chips C2 of each stacked glass substrate 2 can be electrically connected to a corresponding one of the middle conductive circuit layers 21, and the middle conductive circuit layer 21 of each stacked glass substrate 2 can be electrically connected to a corresponding one of the first conductive penetration bodies 4 (for example, each first conductive penetration body 4 has a first exposed extension portion disposed on the bottom side thereof). In addition, the top glass substrate 3 can be configured to provide a top conductive circuit layer 31 (or a top circuit layout layer) and to carry a plurality of top semiconductor chips C3 (such as a memory IC chip, a micro component IC chip, a logic IC chip, or an analog IC chip), the top semiconductor chips C3 can be electrically connected to the top conductive circuit layer 31, and the top conductive circuit layer 31 can be electrically connected to the second conductive penetration body 5 (for example, the second conductive penetration body 5 has a second exposed extension portion disposed on the bottom side thereof). However, the aforementioned details are disclosed for exemplary purposes only, and are not meant to limit the scope of the present disclosure.

For example, referring to FIG. 3 and FIG. 4, each of the first conductive penetration bodies 4 can be configured as a first solid conductor (such as a solid copper pillar or a solid conductive pillars made of any conductive material) or a first hollow conductor (such as a through glass via), and the second conductive penetration body 5 can be configured as a second solid conductor (such as a solid copper pillar or a solid conductive pillars made of any conductive material) or a second hollow conductor (such as a through glass via). More particularly, the first conductive penetration body 4 that is configured to penetrate the bottommost stacked glass substrate 2 can be electrically connected between the middle conductive circuit layer 21 of the bottommost stacked glass substrate 2 and the basic conductive circuit layer 11 of the basic glass substrate 1, the two middle conductive circuit layers 21 of the two stacked glass substrates 2 that are configured to be adjacent to each other can be electrically connected to each other through the corresponding first conductive penetration body 4, and the second conductive penetration body 5 that is configured to penetrate the top glass substrate 3 can be electrically connected between the top conductive circuit layer 31 of the top glass substrate 3 and the middle conductive circuit layer 21 of the topmost stacked glass substrate 2. It should be noted that as shown in FIG. 2, the basic glass substrate 1 provided with the basic conductive circuit layer 11 and the basic semiconductor chips C1 can be configured to cooperate with each other to form a basic glass substrate structure S1 (or a basic glass circuit structure), each of the stacked glass substrates 2 correspondingly provided with the middle conductive circuit layer 21 and the middle semiconductor chips C2, and a corresponding one of the first conductive penetration bodies 4 can be configured to cooperate with each other to form a stacked glass substrate structure S2 (or a stacked glass circuit structure), and the top glass substrate 3 provided with the top conductive circuit layer 31, the top semiconductor chips C3 and the second conductive penetration body 5 can be configured to cooperate with each other to form a top glass substrate structure S3 (or a top glass circuit structure). However, the aforementioned details are disclosed for exemplary purposes only, and are not meant to limit the scope of the present disclosure.

For example, referring to FIG. 3 and FIG. 4, the basic glass substrate 1 has a basic glass adhesive portion 100 around the basic glass substrate 1. In one of the feasible embodiments, the basic glass adhesive portion 100 of the basic glass substrate 1 can be disposed on a top side (or a top surface) of the basic glass substrate 1. In addition, the basic glass adhesive portion 100 of the basic glass substrate 1 can be configured as a basic surrounding glass adhesive layer that is continuous or discontinuous, and the basic glass adhesive portion 100 can be configured to be an inseparable material portion that is provided by the basic glass substrate 1 (that is to say, the basic glass adhesive portion 100 may be a basic glass material deformation portion formed by the basic glass substrate 1 after being heated and cured by the laser beam L). However, the aforementioned details are disclosed for exemplary purposes only, and are not meant to limit the scope of the present disclosure.

For example, referring to FIG. 3 and FIG. 4, each of the stacked glass substrates 2 has a first stacked glass adhesive portion 201 and a second stacked glass adhesive portion 202 therearound. In one of the feasible embodiments, the first stacked glass adhesive portion 201 and the second stacked glass adhesive portion 202 of each stacked glass substrate 2 can be respectively disposed on a bottom side (or a bottom surface) and a top side (or a top surface) of the stacked glass substrate 2. Moreover, the first stacked glass adhesive portion 201 of each stacked glass substrate 2 can be configured as a first surrounding stacked glass adhesive layer that is continuous or discontinuous, the second stacked glass adhesive portion 202 of each stacked glass substrate 2 can be configured as a second surrounding stacked glass adhesive layer that is continuous or discontinuous. In addition, each of the first stacked glass adhesive portions 201 can be configured to be an inseparable material portion that is provided by a corresponding one of the stacked glass substrate 2 (that is to say, the first stacked glass adhesive portion 201 may be a first stacked glass material deformation portion formed by the stacked glass substrate 2 after being heated and cured by the laser beam L), and each of the second stacked glass adhesive portions 202 can be configured to be an inseparable material portion provided by the corresponding stacked glass substrate 2 (that is to say, the second stacked glass adhesive portion 202 may be a second stacked glass material deformation portion formed by the stacked glass substrate 2 after being heated and cured by the laser beam L). However, the aforementioned details are disclosed for exemplary purposes only, and are not meant to limit the scope of the present disclosure.

For example, referring to FIG. 3 and FIG. 4, the top glass substrate 3 has a top glass adhesive portion 300 around the top glass substrate 3. In one of the feasible embodiments, the top glass adhesive portion 300 of the top glass substrate 3 can be disposed on a bottom side (or a bottom surface) of the top glass substrate 3. In addition, the top glass adhesive portion 300 of the top glass substrate 3 can be configured as a top surrounding glass adhesive layer that is continuous or discontinuous, and the top glass adhesive portion 300 can be configured to be an inseparable material portion that is provided by the top glass substrate 3 (that is to say, the top glass adhesive portion 300 may be a top glass material deformation portion formed by the top glass substrate 3 after being heated and cured by the laser beam L). However, the aforementioned details are disclosed for exemplary purposes only, and are not meant to limit the scope of the present disclosure.

It should be noted that, for example, as shown in FIG. 4, a vertical projection (or a perpendicular projection) of the basic glass adhesive portion 100 of the basic glass substrate 1, a vertical projection (or a perpendicular projection) of the first stacked glass adhesive portion 201 and a vertical projection (or a perpendicular projection) of the second stacked glass adhesive portion 202 of each stacked glass substrate 2, and a vertical projection (or a perpendicular projection) of the top glass adhesive portion 300 of the top glass substrate 3 do not fall onto the basic conductive circuit layer 11 of the basic glass substrate 1, the middle conductive circuit layer 21 of each stacked glass substrate 2, and the top conductive circuit layer 31 of the top glass substrate 3. That is to say, the basic conductive circuit layer 11 of the basic glass substrate 1, the middle conductive circuit layer 21 of each stacked glass substrate 2, and the top conductive circuit layer 31 of the top glass substrate 3 do not be damaged during the process of forming the basic glass adhesive portion 100, the first stacked glass adhesive portion 201, the second stacked glass adhesive portion 202 and the top glass adhesive portion 300 by heating and curing with the laser beam L. However, the aforementioned details are disclosed for exemplary purposes only, and are not meant to limit the scope of the present disclosure.

Therefore, the basic glass adhesive portion 100 of the basic glass substrate 1 and the first stacked glass adhesive portion 201 of the bottommost stacked glass substrate 2 can be connected to each other and disposed between the basic glass substrate 1 and the bottommost stacked glass substrate 2, so that the basic glass substrate 1 and the bottommost stacked glass substrate 2 can be configured to be connected to each other through “the basic glass adhesive portion 100 of the basic glass substrate 1 (or the basic glass adhesive portion 100 formed by heating and curing with the laser beam L)” and “the first stacked glass adhesive portion 201 of the bottommost stacked glass substrate 2 (or the first stacked glass adhesive portion 201 formed by heating and curing with the laser beam L).” Moreover, the first stacked glass adhesive portion 201 and the second stacked glass adhesive portion 202 that are configured to be adjacent to each other can be connected to each other and disposed between the two adjacent stacked glass substrates 2, so that the two adjacent stacked glass substrates 2 can be configured to be connected to each other through “the first stacked glass adhesive portion 201 (or the first stacked glass adhesive portion 201 formed by heating and curing with the laser beam L)” and “the second stacked glass adhesive portion 202 (or the second stacked glass adhesive portion 202 formed by heating and curing with the laser beam L)” that are adjacent to each other. In addition, the top glass adhesive portion 300 of the top glass substrate 3 and the second stacked glass adhesive portion 202 of the topmost stacked glass substrate 2 can be connected to each other and disposed between the top glass substrate 3 and the topmost stacked glass substrate 2, so that the top glass substrate 3 and the topmost stacked glass substrate 2 can be configured to be connected to each other through “the top glass adhesive portion 300 of the top glass substrate 3 (or the top glass adhesive portion 300 formed by heating and curing with the laser beam L)” and “the second stacked glass adhesive portion 202 of the topmost stacked glass substrate 2 (or the second stacked glass adhesive portion 202 formed by heating and curing with the laser beam L).” That is to say, the basic glass adhesive portion 100 of the basic glass substrate 1, the first stacked glass adhesive portion 201 and the second stacked glass adhesive portion 202 of each stacked glass substrate 2, and the top glass adhesive portion 300 of the top glass substrate 3 can cooperate with each other, thereby bonding the basic glass substrate 1, the plurality of stacked glass substrates 2 and the top glass substrate 3 together.

### Second Embodiment

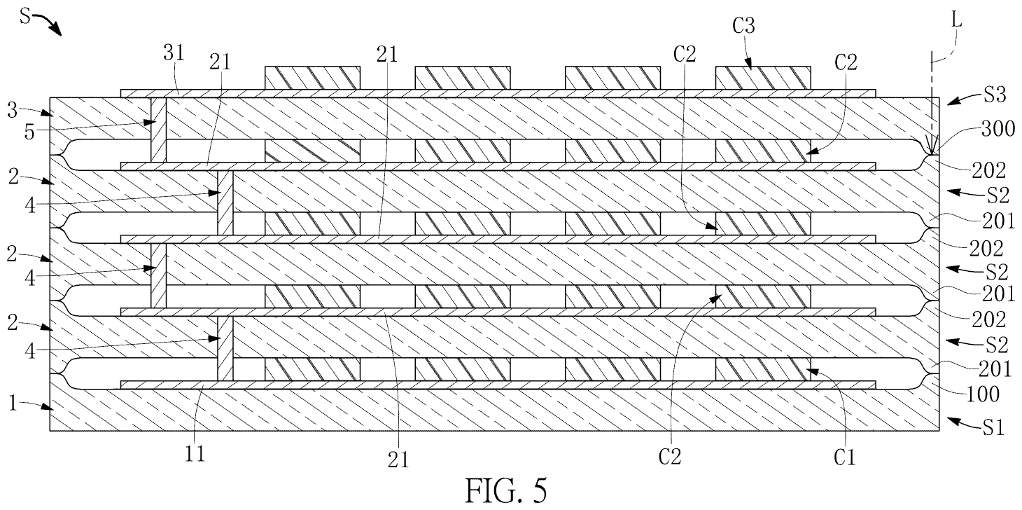

Referring to FIG. 5, a second embodiment of the present disclosure provides a glass substrate stacking structure S, which may at least include a basic glass substrate 1, a plurality of stacked glass substrates 2, a top glass substrate 3, a plurality of first conductive penetration bodies 4 and a second conductive penetration body 5. Comparing FIG. 5 with FIG. 4, the main difference between the second embodiment and the first embodiment is as follows: in the second embodiment, the basic glass adhesive portion 100 of the basic glass substrate 1, the first stacked glass adhesive portion 201 and the second stacked glass adhesive portion 202 of each stacked glass substrate 2, and the top glass adhesive portion 300 of the top glass substrate 3 can be connected with each other, thereby bonding the basic glass substrate 1, the plurality of stacked glass substrates 2 and the top glass substrate 3 together. It should be noted that the basic glass adhesive portion 100 of the basic glass substrate 1, the first stacked glass adhesive portion 201 and the second stacked glass adhesive portion 202 of each stacked glass substrate 2, and the top glass adhesive portion 300 of the top glass substrate 3 can cooperate with each other to form a continuous or discontinuous surrounding adhesive structure. However, the aforementioned details are disclosed for exemplary purposes only, and are not meant to limit the scope of the present disclosure.

### Third Embodiment

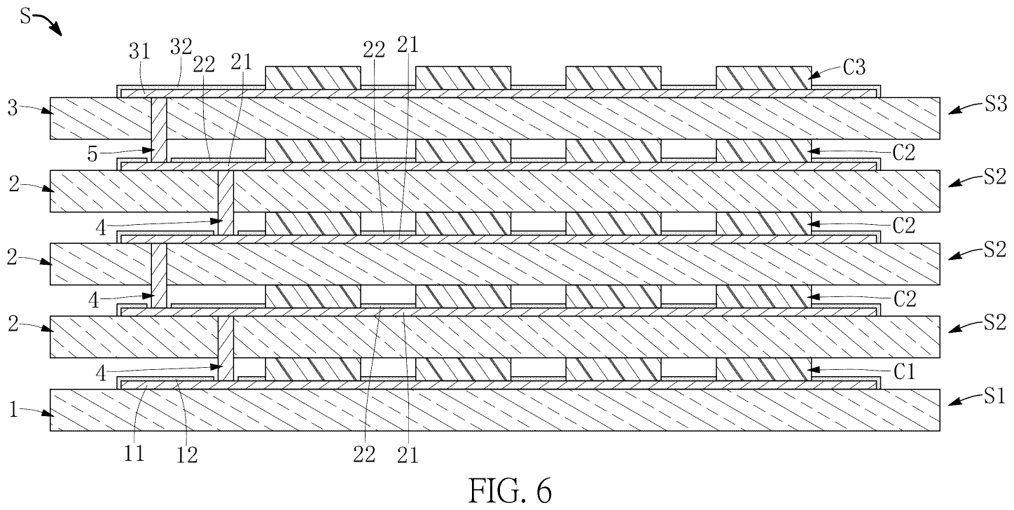

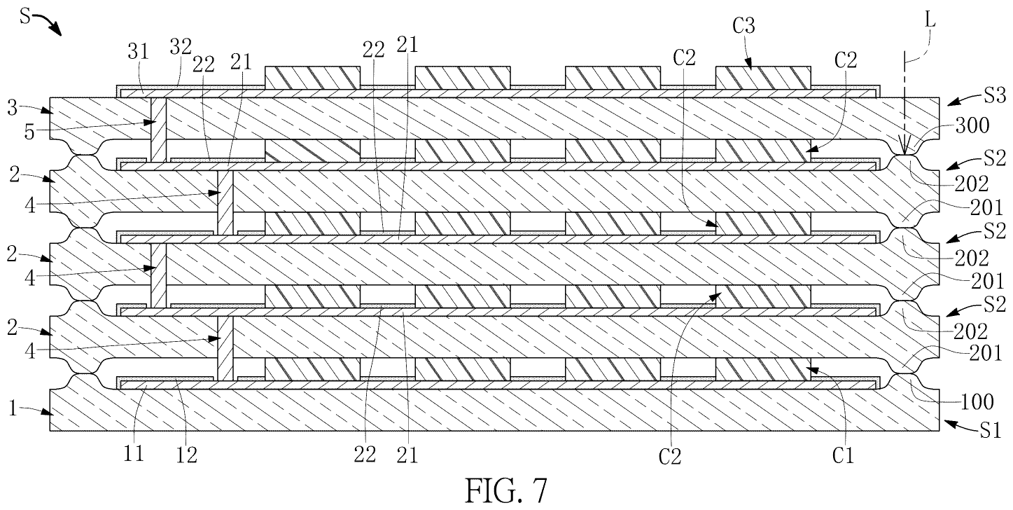

Referring to FIG. 6 and FIG. 7, a third embodiment of the present disclosure provides a glass substrate stacking structure S, which may at least include a basic glass substrate 1, a plurality of stacked glass substrates 2, a top glass substrate 3, a plurality of first conductive penetration bodies 4 and a second conductive penetration body 5. Comparing FIG. 6 with FIG. 3, and comparing FIG. 7 with FIG. 4, the main difference between the third embodiment and the first embodiment is as follows: in the third embodiment, the basic glass substrate 1 can be configured to provide a basic circuit protection layer 12 (such as a solder mask, a solder resist or any insulating material layer) for covering or protecting the basic conductive circuit layer 11, each of the stacked glass substrates 2 can be configured to provide a middle circuit protection layer 22 (such as a solder mask, a solder resist or any insulating material layer) for covering or protecting the corresponding middle conductive circuit layer 21, and the top glass substrate 3 can be configured to provide a top circuit protection layer 32 (such as a solder mask, a solder resist or any insulating material layer) for covering or protecting the top conductive circuit layer 31. However, the aforementioned details are disclosed for exemplary purposes only, and are not meant to limit the scope of the present disclosure.

### Fourth Embodiment

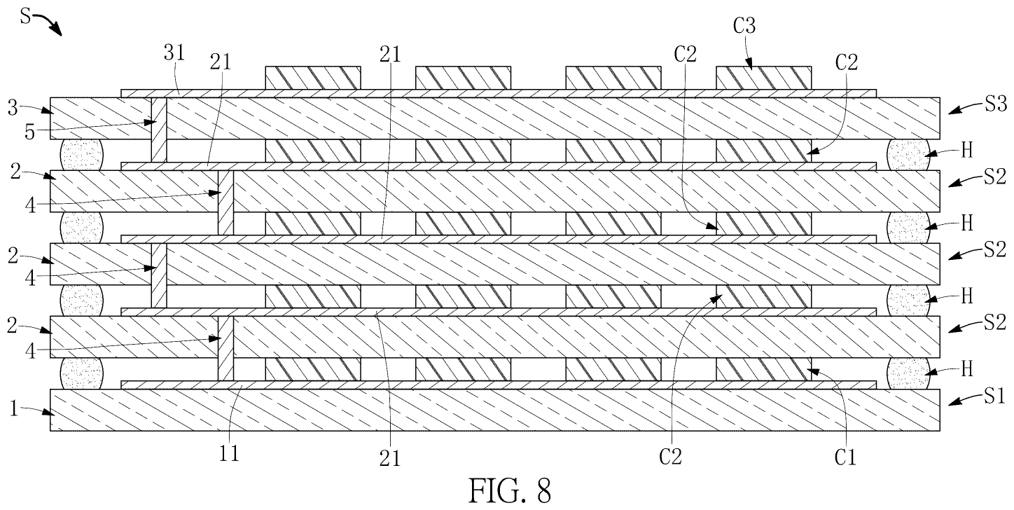

Referring to FIG. 8, a fourth embodiment of the present disclosure provides a glass substrate stacking structure S, which may at least include a basic glass substrate 1, a plurality of stacked glass substrates 2, a top glass substrate 3, a plurality of first conductive penetration bodies 4 and a second conductive penetration body 5. Comparing FIG. 8 with FIG. 4, the main difference between the fourth embodiment and the first embodiment is as follows: in the fourth embodiment, the basic glass adhesive portion can be configured to be a separable material portion (such as a basic material portion provided additionally) that is not provided by the basic glass substrate 1, each of the first stacked glass adhesive portions can be configured to be a separable material portion (such as a first material portion provided additionally) that is not provided by the corresponding stacked glass substrate 2, and each of the second stacked glass adhesive portions can be configured to be a separable material portion (such as a second material portion provided additionally) that is not provided by the corresponding stacked glass substrate 2, and the top glass adhesive portion can be configured to be a separable material portion (such as a top material portion provided additionally) that is not provided by the top glass substrate 3. It should be noted that two adjacent separable material portions can be combined into a glass bonding material H (such as a continuous or discontinuous surrounding adhesive structure), and the plurality of glass bonding materials H can cooperate with each other to bond the basic glass substrate 1, the plurality of stacked glass substrates 2 and the top glass substrate 3 together. For example, the separable material portion can be configured as an acrylic resin portion, an epoxy resin portion, a silicone portion or a glass glue portion. However, the aforementioned details are disclosed for exemplary purposes only, and are not meant to limit the scope of the present disclosure.

### Fifth Embodiment

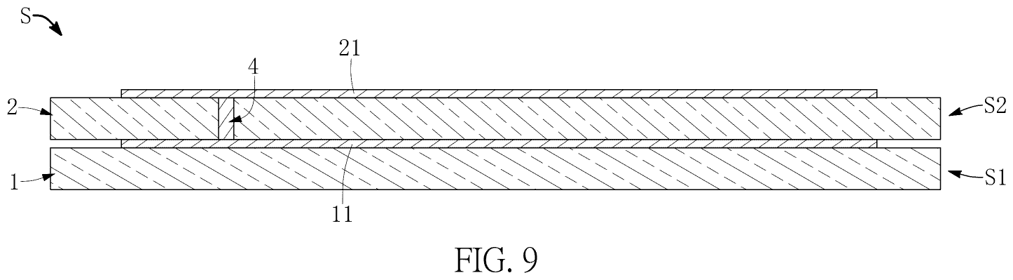

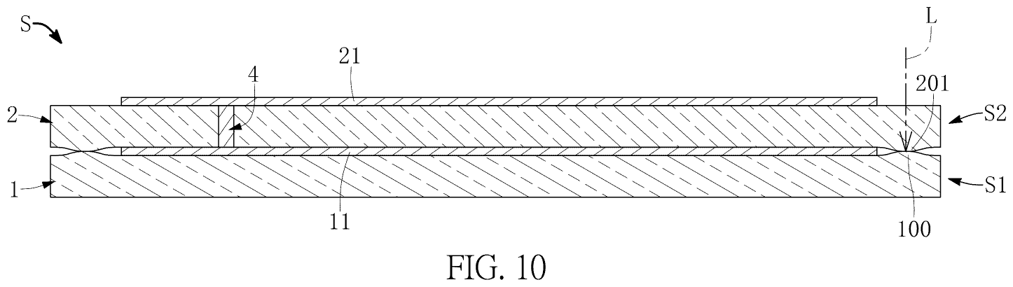

Referring to FIG. 9 and FIG. 10, a fifth embodiment of the present disclosure provides a glass substrate stacking structure S, which may at least include a basic glass substrate structure S1 (or a basic glass circuit structure) and a stacked glass substrate structure S2 (or a stacked glass circuit structure). More particularly, the basic glass substrate structure S1 includes a basic glass substrate 1 provided with a basic conductive circuit layer 11, and the basic glass substrate 1 may not need to carry a plurality of basic semiconductor chips. In addition, the stacked glass substrate structure S2 includes a stacked glass substrate 2 provided with a middle conductive circuit layer 21, and at least one first conductive penetration body 4, and the stacked glass substrate 2 may not need to carry a plurality of middle semiconductor chips. It should be noted that the basic glass adhesive portion 100 of the basic glass substrate 1 and the first stacked glass adhesive portion 201 of the stacked glass substrate 2 can be connected with each other, thereby bonding the basic glass substrate 1 and the stacked glass substrate 2 together.

### Beneficial Effects of the Embodiments

In conclusion, in the glass substrate stacking structure S provided by the present disclosure, by virtue of “the basic glass substrate 1 having a basic glass adhesive portion 100 therearound,” “each of the stacked glass substrates 2 having a first stacked glass adhesive portion 201 and a second stacked glass adhesive portion 202 therearound” and “the top glass substrate 3 having a top glass adhesive portion 300 therearound,” when the basic glass substrate 1, the stacked glass substrates 2 and the top glass substrate 3 are stacked in sequence, the basic glass substrate 1 and a bottommost one of the stacked glass substrates 2 can be configured to be connected to each other through the basic glass adhesive portion 100 of the basic glass substrate 1 and the first stacked glass adhesive portion 201 of the bottommost stacked glass substrate 2, two adjacent ones of the stacked glass substrates 2 can be configured to be connected to each other through the first stacked glass adhesive portion 201 and the second stacked glass adhesive portion 202 that are adjacent to each other, and the top glass substrate 3 and the topmost stacked glass substrate 2 can be configured to be connected to each other through the top glass adhesive portion 300 of the top glass substrate 3 and the second stacked glass adhesive portion 202 of the topmost stacked glass substrate 2.

Moreover, in the method of manufacturing the glass substrate stacking structure S provided by the present disclosure, by virtue of “each of the glass substrates having at least one glass adhesive portion provided by the glass substrate itself and disposed therearound,” when the glass substrates stacked in sequence, two adjacent ones of the glass substrates can be connected to each other through two adjacent ones of the glass adhesive portions.

Furthermore, in the method of manufacturing the glass substrate stacking structure S provided by the present disclosure, by virtue of “the basic glass substrate 1 having a basic glass adhesive portion 100 therearound,” “each of the stacked glass substrates 2 having a first stacked glass adhesive portion 201 and a second stacked glass adhesive portion 202 therearound” and “the top glass substrate 3 having a top glass adhesive portion 300 therearound,” when the basic glass substrate 1, the stacked glass substrates 2 and the top glass substrate 3 are stacked in sequence, the basic glass substrate 1 and a bottommost one of the stacked glass substrates 2 can be configured to be connected to each other through the basic glass adhesive portion 100 of the basic glass substrate 1 and the first stacked glass adhesive portion 201 of the bottommost stacked glass substrate 2, two adjacent ones of the stacked glass substrates 2 can be configured to be connected to each other through the first stacked glass adhesive portion 201 and the second stacked glass adhesive portion 202 that are adjacent to each other, and the top glass substrate 3 and the topmost stacked glass substrate 2 can be configured to be connected to each other through the top glass adhesive portion 300 of the top glass substrate 3 and the second stacked glass adhesive portion 202 of the topmost stacked glass substrate 2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A glass substrate stacking structure, comprising:
a basic glass substrate;
a plurality of stacked glass substrates, wherein the plurality of stacked glass substrates are sequentially stacked on the basic glass substrate;
a top glass substrate stacked on a topmost one of the plurality of stacked glass substrates;
a plurality of first conductive penetration bodies configured to respectively pass through the plurality of stacked glass substrates; and
a second conductive penetration body configured to pass through the top glass substrate;
wherein the basic glass substrate has a basic glass adhesive portion therearound, each of the plurality of stacked glass substrates has a first stacked glass adhesive portion and a second stacked glass adhesive portion therearound, and the top glass substrate has a top glass adhesive portion therearound;
wherein the basic glass substrate and a bottommost one of the plurality of stacked glass substrates are configured to be connected to each other through the basic glass adhesive portion of the basic glass substrate and the first stacked glass adhesive portion of the bottommost stacked glass substrate;
wherein two adjacent ones of the plurality of stacked glass substrates are configured to be connected to each other through the first stacked glass adhesive portion and the second stacked glass adhesive portion that are adjacent to each other; and
wherein the top glass substrate and the topmost stacked glass substrate are configured to be connected to each other through the top glass adhesive portion of the top glass substrate and the second stacked glass adhesive portion of the topmost stacked glass substrate.

2. The glass substrate stacking structure according to claim 1,
wherein the basic glass substrate is configured to provide a basic conductive circuit layer and to carry a plurality of basic semiconductor chips, and the plurality of basic semiconductor chips are electrically connected to the basic conductive circuit layer;
wherein each of the plurality of stacked glass substrates is configured to provide a middle conductive circuit layer and to carry a plurality of middle semiconductor chips, the plurality of middle semiconductor chips of each of the plurality of stacked glass substrates are electrically connected to a corresponding one of the middle conductive circuit layers, and the middle conductive circuit layer of each of the plurality of stacked glass substrates is electrically connected to a corresponding one of the first conductive penetration bodies;
wherein the top glass substrate is configured to provide a top conductive circuit layer and to carry a plurality of top semiconductor chips, the plurality of top semiconductor chips are electrically connected to the top conductive circuit layer, and the top conductive circuit layer is electrically connected to the second conductive penetration body;
wherein the first conductive penetration body configured to penetrate the bottommost stacked glass substrate is electrically connected between the middle conductive circuit layer of the bottommost stacked glass substrate and the basic conductive circuit layer of the basic glass substrate, the two middle conductive circuit layers of the two stacked glass substrates configured to be adjacent to each other are electrically connected to each other through the corresponding first conductive penetration body, and the second conductive penetration body configured to penetrate the top glass substrate is electrically connected between the top conductive circuit layer of the top glass substrate and the middle conductive circuit layer of the topmost stacked glass substrate;
wherein the basic glass substrate provided with the basic conductive circuit layer and the plurality of basic semiconductor chips are configured to cooperate with each other to form a basic glass substrate structure, each of the plurality of stacked glass substrates provided with the middle conductive circuit layer and the plurality of middle semiconductor chips, and a corresponding one of the plurality of first conductive penetration bodies are configured to cooperate with each other to form a stacked glass substrate structure, and the top glass substrate provided with the top conductive circuit layer, the plurality of top semiconductor chips and the second conductive penetration body are configured to cooperate with each other to form a top glass substrate structure;
wherein the basic glass substrate is configured to provide a basic circuit protection layer for covering the basic conductive circuit layer, each of the plurality of stacked glass substrates is configured to provide a middle circuit protection layer for covering the corresponding middle conductive circuit layer, and the top glass substrate is configured to provide a top circuit protection layer for covering the top conductive circuit layer; and
wherein a vertical projection of the basic glass adhesive portion of the basic glass substrate, a vertical projection of the first stacked glass adhesive portion and a vertical projection of the second stacked glass adhesive portion of each of the plurality of stacked glass substrates, and a vertical projection of the top glass adhesive portion of the top glass substrate do not fall onto the basic conductive circuit layer of the basic glass substrate, the middle conductive circuit layer of each of the plurality of stacked glass substrates, and the top conductive circuit layer of the top glass substrate.

3. The glass substrate stacking structure according to claim 1,
wherein the basic glass substrate has a thickness less than or equal to 100 μm, each of the plurality of stacked glass substrates has a thickness less than or equal to 100 μm, and the top glass substrate has a thickness less than or equal to 100 μm;
wherein each of the first conductive penetration bodies is configured as a first solid conductor or a first hollow conductor, and the second conductive penetration body is configured as a second solid conductor or a second hollow conductor;
wherein the basic glass adhesive portion of the basic glass substrate is disposed on a top side of the basic glass substrate, the first stacked glass adhesive portion and the second stacked glass adhesive portion of each of the plurality of stacked glass substrates are respectively disposed on a bottom side and a top side of the plurality of stacked glass substrate, and the top glass adhesive portion of the top glass substrate is disposed on a bottom side of the top glass substrate;
wherein the basic glass adhesive portion of the basic glass substrate is configured as a basic surrounding glass adhesive layer that is continuous or discontinuous, the first stacked glass adhesive portion of each of the plurality of stacked glass substrates is configured as a first surrounding stacked glass adhesive layer that is continuous or discontinuous, the second stacked glass adhesive portion of each of the plurality of stacked glass substrates is configured as a second surrounding stacked glass adhesive layer that is continuous or discontinuous, and the top glass adhesive portion of the top glass substrate is configured as a top surrounding glass adhesive layer that is continuous or discontinuous;
wherein the basic glass adhesive portion is configured to be an inseparable material portion provided by the basic glass substrate or a separable material portion not provided by the basic glass substrate, each of the first stacked glass adhesive portions is configured to be an inseparable material portion provided by a corresponding one of the plurality of stacked glass substrate or a separable material portion not provided by the corresponding stacked glass substrate, and each of the second stacked glass adhesive portions is configured to be an inseparable material portion provided by the corresponding stacked glass substrate or a separable material portion not provided by the corresponding stacked glass substrate, the top glass adhesive portion is configured to be an inseparable material portion provided by the top glass substrate or a separable material portion not provided by the top glass substrate; and
wherein the separable material portion is configured as an acrylic resin portion, an epoxy resin portion, a silicone portion or a glass glue portion.

4. The glass substrate stacking structure according to claim 1,
wherein the basic glass adhesive portion of the basic glass substrate, the first stacked glass adhesive portion and the second stacked glass adhesive portion of each of the plurality of stacked glass substrates, and the top glass adhesive portion of the top glass substrate cooperate with each other; and
wherein the basic glass adhesive portion of the basic glass substrate and the first stacked glass adhesive portion of the bottommost stacked glass substrate are connected to each other and disposed between the basic glass substrate and the bottommost stacked glass substrate, the first stacked glass adhesive portion and the second stacked glass adhesive portion that are configured to be adjacent to each other are connected to each other and disposed between two adjacent ones of the plurality of stacked glass substrates, and the top glass adhesive portion of the top glass substrate and the second stacked glass adhesive portion of the topmost stacked glass substrate are connected to each other and disposed between the top glass substrate and the topmost stacked glass substrate.

5. The glass substrate stacking structure according to claim 1,
wherein the basic glass adhesive portion of the basic glass substrate, the first stacked glass adhesive portion and the second stacked glass adhesive portion of each of the plurality of stacked glass substrates, and the top glass adhesive portion of the top glass substrate are connected with each other; and
wherein the basic glass adhesive portion of the basic glass substrate, the first stacked glass adhesive portion and the second stacked glass adhesive portion of each of the plurality of stacked glass substrates, and the top glass adhesive portion of the top glass substrate cooperate with each other to form a continuous or discontinuous surrounding adhesive structure.

6. A glass substrate stacking structure, comprising a plurality of glass substrates stacked in sequence, at least one of the plurality of glass substrates being penetrated by a conductive penetration body, each of the plurality of glass substrates having at least one glass adhesive portion provided by the glass substrate itself and disposed therearound, two adjacent ones of the plurality of glass substrates being connected to each other through two adjacent ones of the plurality of glass adhesive portions, and each of the plurality of glass substrates having a thickness less than or equal to 100 μm.

7. A method of manufacturing a glass substrate stacking structure, comprising:
providing a basic glass substrate, a plurality of stacked glass substrates and a top glass substrate;
stacking the basic glass substrate, the plurality of stacked glass substrates and the top glass substrate in sequence; and
bonding the basic glass substrate, the plurality of stacked glass substrates and the top glass substrate together by laser processing;
wherein a plurality of first conductive penetration bodies are configured to respectively pass through the plurality of stacked glass substrates, and a second conductive penetration body is configured to pass through the top glass substrate;
wherein the basic glass substrate has a basic glass adhesive portion therearound, each of the plurality of stacked glass substrates has a first stacked glass adhesive portion and a second stacked glass adhesive portion therearound, and the top glass substrate has a top glass adhesive portion therearound;
wherein the basic glass substrate and a bottommost one of the plurality of stacked glass substrates are configured to be connected to each other through the basic glass adhesive portion of the basic glass substrate and the first stacked glass adhesive portion of the bottommost stacked glass substrate;
wherein two adjacent ones of the plurality of stacked glass substrates are configured to be connected to each other through the first stacked glass adhesive portion and the second stacked glass adhesive portion that are adjacent to each other; and
wherein the top glass substrate and the topmost stacked glass substrate are configured to be connected to each other through the top glass adhesive portion of the top glass substrate and the second stacked glass adhesive portion of the topmost stacked glass substrate.

8. The method according to claim 7,
wherein the basic glass substrate is configured to provide a basic conductive circuit layer and to carry a plurality of basic semiconductor chips, and the plurality of basic semiconductor chips are electrically connected to the basic conductive circuit layer;
wherein each of the plurality of stacked glass substrates is configured to provide a middle conductive circuit layer and to carry a plurality of middle semiconductor chips, the plurality of middle semiconductor chips of each of the plurality of stacked glass substrates are electrically connected to a corresponding one of the middle conductive circuit layers, and the middle conductive circuit layer of each of the plurality of stacked glass substrates is electrically connected to a corresponding one of the first conductive penetration bodies;
wherein the top glass substrate is configured to provide a top conductive circuit layer and to carry a plurality of top semiconductor chips, the plurality of top semiconductor chips are electrically connected to the top conductive circuit layer, and the top conductive circuit layer is electrically connected to the second conductive penetration body;
wherein the first conductive penetration body configured to penetrate the bottommost stacked glass substrate is electrically connected between the middle conductive circuit layer of the bottommost stacked glass substrate and the basic conductive circuit layer of the basic glass substrate, the two middle conductive circuit layers of the two stacked glass substrates configured to be adjacent to each other are electrically connected to each other through the corresponding first conductive penetration body, and the second conductive penetration body configured to penetrate the top glass substrate is electrically connected between the top conductive circuit layer of the top glass substrate and the middle conductive circuit layer of the topmost stacked glass substrate;
wherein the basic glass substrate provided with the basic conductive circuit layer and the plurality of basic semiconductor chips are configured to cooperate with each other to form a basic glass substrate structure, each of the plurality of stacked glass substrates provided with the middle conductive circuit layer and the plurality of middle semiconductor chips, and a corresponding one of the plurality of first conductive penetration bodies are configured to cooperate with each other to form a stacked glass substrate structure, and the top glass substrate provided with the top conductive circuit layer, the plurality of top semiconductor chips and the second conductive penetration body are configured to cooperate with each other to form a top glass substrate structure;
wherein the basic glass substrate is configured to provide a basic circuit protection layer for covering the basic conductive circuit layer, each of the plurality of stacked glass substrates is configured to provide a middle circuit protection layer for covering the corresponding middle conductive circuit layer, and the top glass substrate is configured to provide a top circuit protection layer for covering the top conductive circuit layer; and
wherein a vertical projection of the basic glass adhesive portion of the basic glass substrate, a vertical projection of the first stacked glass adhesive portion and a vertical projection of the second stacked glass adhesive portion of each of the plurality of stacked glass substrates, and a vertical projection of the top glass adhesive portion of the top glass substrate do not fall onto the basic conductive circuit layer of the basic glass substrate, the middle conductive circuit layer of each of the plurality of stacked glass substrates, and the top conductive circuit layer of the top glass substrate.

9. The method according to claim 7,
wherein the basic glass substrate has a thickness less than or equal to 100 μm, each of the plurality of stacked glass substrates has a thickness less than or equal to 100 μm, and the top glass substrate has a thickness less than or equal to 100 μm;
wherein each of the first conductive penetration bodies is configured as a first solid conductor or a first hollow conductor, and the second conductive penetration body is configured as a second solid conductor or a second hollow conductor;
wherein the basic glass adhesive portion of the basic glass substrate is disposed on a top side of the basic glass substrate, the first stacked glass adhesive portion and the second stacked glass adhesive portion of each of the plurality of stacked glass substrates are respectively disposed on a bottom side and a top side of the plurality of stacked glass substrate, and the top glass adhesive portion of the top glass substrate is disposed on a bottom side of the top glass substrate;
wherein the basic glass adhesive portion of the basic glass substrate is configured as a basic surrounding glass adhesive layer that is continuous or discontinuous, the first stacked glass adhesive portion of each of the plurality of stacked glass substrates is configured as a first surrounding stacked glass adhesive layer that is continuous or discontinuous, the second stacked glass adhesive portion of each of the plurality of stacked glass substrates is configured as a second surrounding stacked glass adhesive layer that is continuous or discontinuous, and the top glass adhesive portion of the top glass substrate is configured as a top surrounding glass adhesive layer that is continuous or discontinuous;
wherein the basic glass adhesive portion is configured to be an inseparable material portion provided by the basic glass substrate or a separable material portion not provided by the basic glass substrate, each of the first stacked glass adhesive portions is configured to be an inseparable material portion provided by a corresponding one of the plurality of stacked glass substrate or a separable material portion not provided by the corresponding stacked glass substrate, and each of the second stacked glass adhesive portions is configured to be an inseparable material portion provided by the corresponding stacked glass substrate or a separable material portion not provided by the corresponding stacked glass substrate, the top glass adhesive portion is configured to be an inseparable material portion provided by the top glass substrate or a separable material portion not provided by the top glass substrate; and
wherein the separable material portion is configured as an acrylic resin portion, an epoxy resin portion, a silicone portion or a glass glue portion.

10. The method according to claim 7,
wherein the basic glass adhesive portion of the basic glass substrate, the first stacked glass adhesive portion and the second stacked glass adhesive portion of each of the plurality of stacked glass substrates, and the top glass adhesive portion of the top glass substrate cooperate with each other or are connected with each other;
wherein, when the basic glass adhesive portion of the basic glass substrate, the first stacked glass adhesive portion and the second stacked glass adhesive portion of each of the plurality of stacked glass substrates, and the top glass adhesive portion of the top glass substrate cooperate with each other, the basic glass adhesive portion of the basic glass substrate and the first stacked glass adhesive portion of the bottommost stacked glass substrate are connected to each other and disposed between the basic glass substrate and the bottommost stacked glass substrate, the first stacked glass adhesive portion and the second stacked glass adhesive portion that are configured to be adjacent to each other are connected to each other and disposed between two adjacent ones of the plurality of stacked glass substrates, and the top glass adhesive portion of the top glass substrate and the second stacked glass adhesive portion of the topmost stacked glass substrate are connected to each other and disposed between the top glass substrate and the topmost stacked glass substrate;
wherein, when the basic glass adhesive portion of the basic glass substrate, the first stacked glass adhesive portion and the second stacked glass adhesive portion of each of the plurality of stacked glass substrates, and the top glass adhesive portion of the top glass substrate are connected with each other, the basic glass adhesive portion of the basic glass substrate, the first stacked glass adhesive portion and the second stacked glass adhesive portion of each of the plurality of stacked glass substrates, and the top glass adhesive portion of the top glass substrate; and
wherein the basic glass adhesive portion of the basic glass substrate, the first stacked glass adhesive portion and the second stacked glass adhesive portion of each of the plurality of stacked glass substrates, and the top glass adhesive portion of the top glass substrate cooperate with each other to form a continuous or discontinuous surrounding adhesive structure.
